(19) United States
(12) Patent Application Publication
(10) Pub. No.: US 2004/0019396 A1
(43) Pub. Date: Jan. 29, 2004

(54) Methods for recording music to optical media

(76) Inventors: Maureen McMahon, Sunnyvale, CA (US); Kenneth R. James, Pleasanton, CA (US)

Correspondence Address: MARTINE & PENILLA, LLP, 710 LAKEWAY DRIVE, SUITE 170, SUNNYVALE, CA, 94085, US

(21) Appl. No.: 09/823,787

(22) Filed: Mar. 30, 2001

(51) Int. Cl. G06F 17/00; H03M 1/00; G11C 5/00

(52) U.S. Cl. 700/94; 84/601

(57) ABSTRACT

Methods, computer readable media, an optical media recording program, and a computer system implementing program instructions for recording music files to optical media are provided. In one example, a method includes selecting a music data project and enabling the browsing of MP3 files at a source location while filtering other data files. Graphical user interfaces provide for the selection of MP3 files to record, and for the construction of a playlist that will play the selected files in order from the destination optical media. The playlist is created and can be edited during the selection of the files to record. The selected files and the playlist are then recorded to the destination optical media along with an autorun file that will enable the launching of a media player and the playing of the MP3 files in accordance with the playlist upon insertion of the optical media in a playback device.

### BACKGROUND OF THE INVENTION

1. Field of the Invention

The present invention relates generally to the recording of music files onto optical media, and more particularly to a method for easily recording and creating optical media containing music data files.

2. Description of the Related Art

The convergence of the music recording and production industry with the computer industry has widely expanded music options for the consumer. The use of optical media for music files enables the enjoyment of quality audio reproduction on home audio systems, automobile audio systems, portable audio systems, a typical computer system, and the like, allowing single-media portability of personal music enjoyment just about anywhere. The advent of recordable optical media ushered in even more options by allowing those of minimum computer skill to create custom collections of desired audio recordings with optical media quality. A typical consumer can create personal, custom optical media of desired audio selections of comparable quality to that available for purchase commercially, but with the specific compilations as desired and created by the individual consumer.

One limitation of audio optical media is the number of songs that can be recorded to a single compact disc. As is known, audio files are very large files and, given the limitation of a typical compact disc having a capacity of approximately 650 megabytes, the number of songs that can be recorded to a single disc typically ranges between about 11 and 16, and even up to about 20, depending on the length of the songs selected.

This limitation of a generally few number of songs that will fit on a typical compact disc has been largely overcome with the use of MPEG1-Layer-3, or .mp3 (MP3) files. MP3 files are standardized file types as described in the standard ISO-MPEG Audio Layer-3 which is herein incorporated by reference. MP3 files, unlike large audio files, are data files which can be read, or “played,” by an application that reads the data and reproduces the audio information contained in the data file. To the average consumer, the clarity and quality of an MP3 file is practically indistinguishable from that of an audio file. The significant advantage of MP3 files is that, as data files, MP3 files are substantially smaller than audio files, and many more songs can be recorded to a single compact disc. By way of example, a typical compact disc of MP3 files can contain about 100-300 songs, depending on the length of each song. Using MP3 files, optical media can now be created containing custom compilations of songs, with a single compact disc containing 100-300 songs.

While the continuing proliferation of MP3 files has provided increased variety and flexibility for the average consumer, the prior art processes for consumers to create optical media containing MP3 files are cumbersome and restrictive. The typical computer user possessing minimum skill is easily confused and frustrated with a recording process that requires more technical skill than that of a typical consumer, and can be confusing for even the more seasoned user. FIG. 1 is a flow chart diagram 10 illustrating the method operations of a typical prior art MP3 recording process. The method begins with operation 12 in which a media recording application is launched. A typical application, such as Easy CD Creator by Roxio, Inc., Milpitas Calif., is used to record audio and data files to optical media.

The method continues with operation 14 in which the media recording application is configured for a data session. One of the more confusing aspects of the prior art methods for creating optical media of MP3 files is that the methods require that the user know and understand that, although the created media “sounds” like audio tracks, MP3 files are actually data files, and the media recording application needs to be configured to record a data, and not an audio session.

The method proceeds with operation 16 in which the source location or locations are searched for data files. As in operation 14, the prior art methods require the user to understand that the process of creating an optical media of MP3 files is a data operation. A user needs to search a source through all data files contained therein for the desired MP3 files. Typically, a filter is not provided to either show only MP3 files, or to filter out some of the large volume of data files that may exist at the source location or locations. Examples of data files include text documents, database information, computer programs, and a majority of the files found on a typical computer system, peripheral device media, internet locations, and the like, and therefore present a considerable volume of files to examine in search of the desired MP3 files.

Next, the method advances to operation 20 where a user can manually create a playlist. A playlist, as is known, is a list of songs in the order of desired playback. The playlist created with prior art, as noted, is valid only for the selected files so long as they remain in their source location or locations. This is because the prior art methods, while allowing some limited capability to make a playlist, provide no capability to project the selected files, in a desired order, to the destination. When a playlist is created, the selected files are mapped to an exact location of each file as identified at the time of the creation of the playlist. The playing or executing of the playlist is then the reading or playing each file at the identified or mapped location. The creation of a playlist is more fully discussed in reference to FIG. 2 below.

The method concludes with operation 22 in which the selected files are recorded to the destination optical media. It should be noted that, although a playlist may have been created in operation 20 above, it was valid only for the selected files in the source location or locations. Once the files are recorded to the destination optical media in operation 22, a user would need to create a new playlist in accordance with the functions and capabilities of whichever media player is used.

As can be appreciated, the illustrated method can become more than a little complicated when large numbers of MP3 files are selected for recording to optical media. In addition to requiring a user to browse through large quantities of data files of all types, the creation of the playlist, when available, does not establish a playlist for the recorded optical media, but only for the source files in their source location or locations. FIG. 2 shows a more detailed flow chart 50 of a typical prior art method of creating a playlist.

The method operations of creating a playlist using prior art methods begin with parallel alternative operations 52 and 53. The prior art requires the user to know and understand that a playlist is a text file. Knowing a playlist file is a text file, the skilled user can open a text editor in operation 52, or in some applications, open a dedicated playlist editor in operation 54. Typically, the dedicated playlist editor would be, for example, incorporated into a system media player application. A media player, as is known, is an application that reads and “plays” media files of various types, including MP3 files, on a computer system. Examples of media players include Winamp™ by Nullsoft, Inc., Dulles, Va., RealJukebox™ by RealNetworks, Inc., Seattle, Wash., Windows Media Player™ by Microsoft, Inc., Redmond, Wash., and the like.

A playlist is similar to a list of pointers to an MP3 or other file, that provides an order and a specific location of MP3 files. When a media player, for example, reads a playlist, the media player is directed in sequence to specific identified locations of named files. The data files are then read or played, reproducing the audio information contained therein. In operation 56, the specific path to each selected file is written into the playlist. As should be appreciated, when the playlist is executed the media player opens a file identified and mapped in the playlist at the source location and reads and plays the audio information contained in the data file. If, as in the present example, the selected MP3 files have not yet been written to the destination drive, e.g. during the preparation for recording an MP3 compact disc, then an error can result if a destination playlist is created and the system recognizes that the files don't exist where the program is told they will exist, or if the map to the source is correctly captured and the playlist is executed after the record operation. In the latter exarnple, the media player executing a playlist mapped to the source could only locate and play the files on the source system, and only if the source files are not moved or deleted after the creation of the playlist. There is no currently known prior art method for creating a playlist for the destination optical media during the selection of source files to be recorded.

The method of FIG. 2 thus terminates at 58 with a playlist that identifies selected files at the source location or locations. In the illustrated example, another playlist would have to be created to select, order, and play MP3 files from the destination drive and media after the files have been recorded. In order to select and arrange the desired MP3 (data) files for playing, the entire volume of files which, as described above, can range between about 100 and 300 files would have to be examined.

In view of the foregoing, there is a need for a method for easily selecting and recording MP3 files to optical media. The method should provide an average computer user an effective method of browsing and selecting from source files without requiring specialized knowledge of the type of file or session that is to be recorded. The method should further provide the average user with the ability to create a desired playlist at the time of file selection for a compact disc of MP3 files, and the method should provide that the playlist created during file selection will execute and play the desired files in the desired order from the destination optical media.

### SUMMARY OF THE INVENTION

Broadly speaking, the present invention fills these needs by providing a method for easily creating MP3 CDs with an application that automatically configures a data session upon selection of an MP3 project, filters files other than MP3 to enable easy browsing of source location, and provides for the creation and editing of a playlist at the time of file selection and before recording. The present invention can be implemented in numerous ways, including as a process, an apparatus, a system, a device, a method, or a computer readable media. Several embodiments of the present invention are described below.

In one embodiment, a method for recording MP3 files to optical media is disclosed. The method includes browsing MP3 files at a source location and selecting MP3 files to record to a destination optical media. The method further includes constructing a playlist of the selected MP3 files to be executed from the destination optical media, and then recording the selected MP3 files and the playlist to the destination optical media.

In another embodiment, a computer readable media having program instructions for recording data to optical media is disclosed. The computer readable media includes program instructions for receiving a project selection, and for configuring and formatting a recording session in accordance with the received project selection. Also included are program instructions for parsing source files and filtering out those files not in a target format of the received project selection. The computer readable media includes program instructions for receiving a selection of source files to be recorded to the optical media, and for constructing a playlist of the source files to be executed from the destination optical media. The selection of source files and the playlist are then recorded to the optical media.

In still a further embodiment, a optical media recording program configured to record data to optical media is disclosed. The program includes instructions for searching for music data files from at least one source. The searching is configured to display only music data files and exclude non-music data files. The optical media recording program further enables the selection of particular ones of the music data files, and builds a data structure including the selected files and a playlist data structure that defines an order for playing the selected music data files. The selected music data files and the playlist data structure are recorded to an optical disc from the at least one source, and configured to be accessed for playing from the optical disc in the order defined by the playlist data structure.

In yet another embodiment, a computer system including an attached peripheral storage device and an attached optical disc recording device is disclosed. The computer system has a processor and memory for executing program instructions stored at least in part in the attached storage device, and the system includes program instructions to receive a project selection and configure a recording session in accordance with the received project selection. Also included are program instructions for parsing source files and filtering out those files not in a format of the received project selection, and for receiving a selection of source files to be recorded to a destination optical media. The system further includes instructions for constructing a playlist of the source files to be executed from the destination optical media, and for recording the selection of source files and the playlist in a format of the received project selection.

The advantages of the present invention are numerous. One notable benefit and advantage of the invention is that, when recording an optical media, a desired project from a plurality of projects available from the media recording application can be selected and a recording session is configured and formatted in accordance with the selected project. A typical user, therefore, need not know that MP3 files are data files or that the resulting recording session is a data recording session and not an audio recording session. Further, when selecting a particular project, a filter is activated to enable the browsing and selection of files for recording in the desired format. If an MP3 project is selected, for example, the various text, data, application, and other data files in a source location are filtered, and only MP3 files are displayed through which to browse and select files for recording. The filter can also be modified to display additional files and file types as desired.

Another significant advantage is the ability to create and edit a playlist at the time of file selection. The playlist, created while the files are in a source location or locations, maps a file path for the files to the destination optical media. The playlist is recorded with the files to the optical media, and then when executed plays the files from the optical media in the order as set during the creation of the playlist. Initially, the playlist adds files in the order they are added to the project, and this order can be maintained or the playlist can be edited prior to recording. In a further embodiment, a previous session playlist is imported and combined with the project enabling additional editing of a previously recorded selection of files while adding new files to the project.

Yet another advantage of the present invention is that when an MP3 project is recorded to optical media, in one embodiment of the invention, an autorun.inf file is recorded with the project. The autorun feature launches an executable file when the recorded optical media is inserted into a playback device which checks the host system for the registration of the playlist (M3U) file, and if associated, will launch the playlist and automatically start playing the optical media in accordance with the playlist.

Other advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, wherein like reference numerals designate like structural elements.

FIG. 1 is a flow chart diagram illustrating the method operations of a typical prior art MP3 recording process.

FIG. 2 shows a more detailed flow chart of a typical prior art method of creating a playlist.

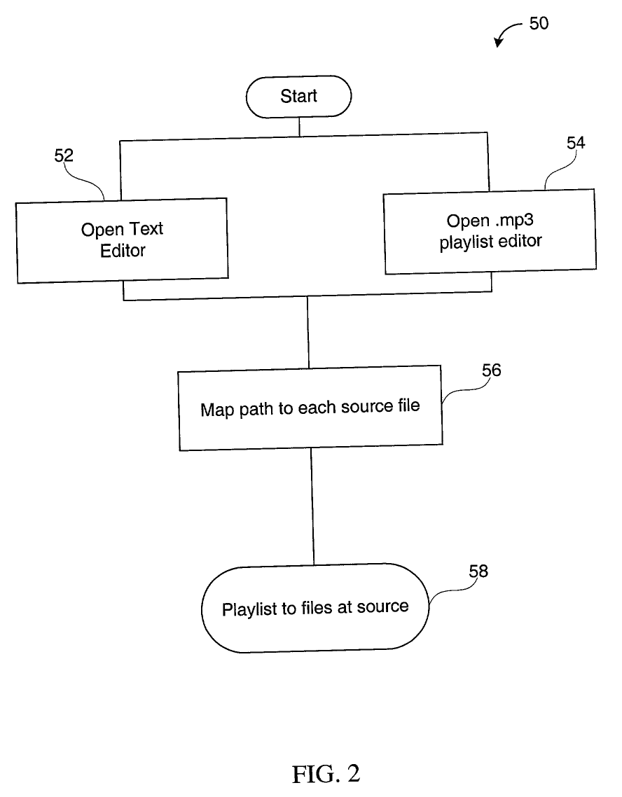

FIG. 3 provides an overview flowchart of one embodiment for creating optical media containing MP3 files.

FIG. 4 shows an exemplary project menu screen for recording MP3 files in accordance with one embodiment of the invention.

FIG. 5 shows an exemplary MP3 CD project screen for recording MP3 files in accordance with one embodiment of the invention.

FIG. 6 shows an exemplary MP3 playlist editor screen for editing the MP3 project playlist in accordance with one embodiment of the invention.

FIG. 7 is a flowchart diagram illustrating the method operations of creating a playlist in accordance with one embodiment of the present invention.

FIG. 8 is a flowchart diagram illustrating in greater detail the method operations performed to create and record optical media containing MP3 files in accordance with one embodiment of the present invention.

FIG. 9 is a flowchart diagram illustrating in greater detail the method operations of building an initial playlist of operations 216 and 220 from FIG. 8.

### DETAILED DESCRIPTION OF THE PREFERRED EMBODIMENTS

Methods and computer readable media with program instructions for easily recording and creating optical media containing MP3 music files are disclosed. In preferred embodiments, the methods provide a user with simple graphic and menu-driven processes to select MP3 files to be recorded to optical media, to create a playlist for the files at the time of selection that will play the files in a desired sequence from the destination media, and to record the selected MP3 files and playlist to optical media. In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to unnecessarily obscure the present invention.

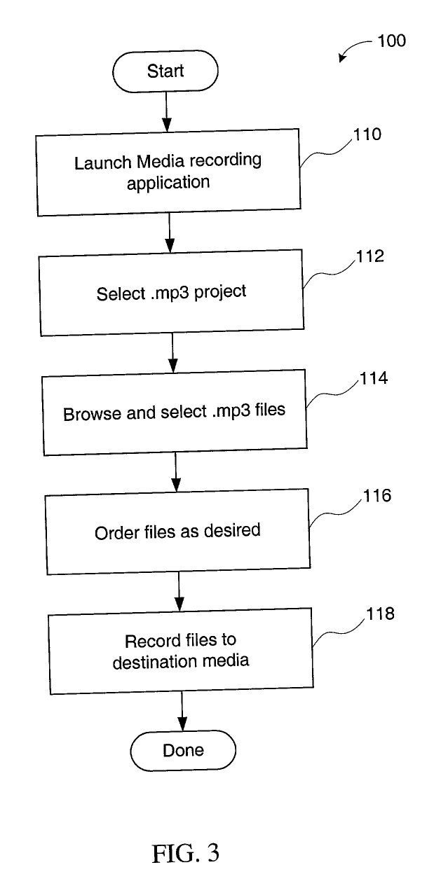

In one embodiment, methods of the present invention provide a user with a simple process for browsing MP3 files at a source location or locations, for selecting files to be recorded to a destination optical media, for creating a playlist to arrange the selected files in a desired sequence for listening, and for recording the selected files to optical media. FIG. 3 provides an overview flowchart 100 of one embodiment for creating optical media containing MP3 files.

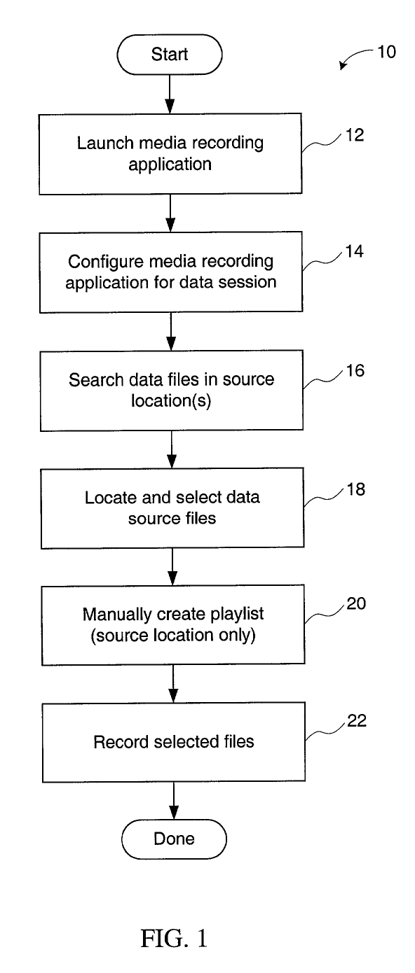

The overview flowchart 100, constructed to mirror the operations of flowchart 10 of FIG. 1, shows the method beginning with operation 110 in which a media recording application is launched. Just as in the prior art described in reference to FIG. 1, a media recording application is used to integrate the tasks of formatting destination media, preparing selected files for recording to destination media, manipulating the data transfer, and other such tasks associated with writing files to a destination optical media.

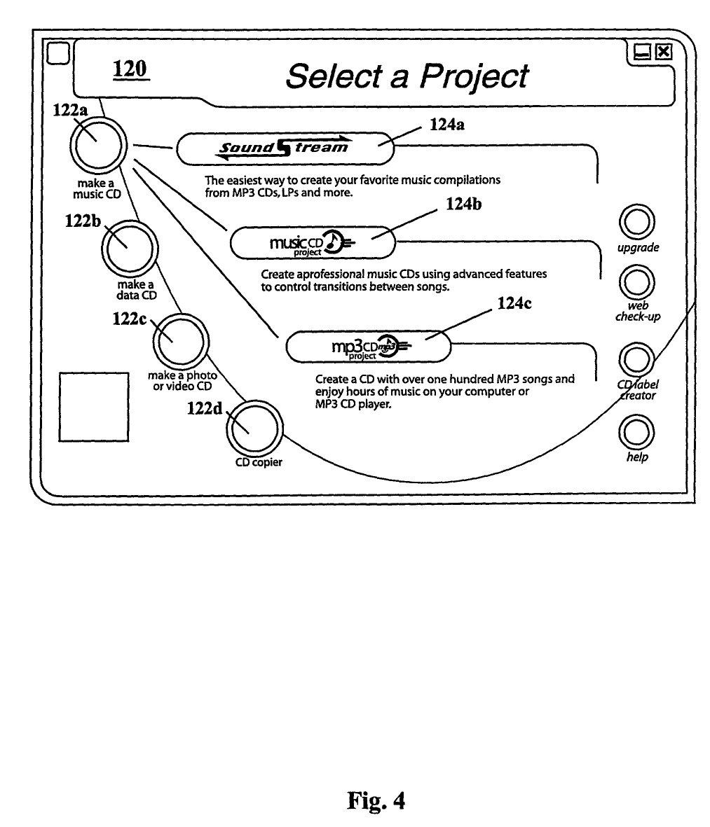

FIG. 4 shows an exemplary project menu screen 120 for recording MP3 files in accordance with one embodiment of the invention. The illustrated project menu screen 120 provides for selection of project categories through selectable project category buttons 122a-122d. By way of example, the selectable project category button 122a provides a user options for the creation of a plurality of music CD projects. In one embodiment, the selection of a project category button 122a-122b presents a plurality of selectable project selection buttons 124a-124c for the selection of a particular music CD project. In the illustrated example, project selection button 124c provides access to a plurality of user-selectable options, and initiates the processes for creating a music CD of MP3 files.

Returning to FIG. 3, the method continues with operation 112 in which an MP3 project is selected. In one embodiment of the present invention, the identification of a project as an MP3 project automatically configures the media recording application for a data session to select and write MP3 data files. Selecting an MP3 project in operation 112 corresponds to selecting an MP3 CD project selection button 124c after having selected a Make A Music CD project category button 122a in FIG. 4. A user is not required to know or understand the format and formatting requirements of MP3 files. A user need only identify the project as that of creating an optical disc of MP3 files, and the necessary configuration is accomplished without user intervention. By way of example, in one embodiment of the present invention, when a user selects an MP3 project, the destination device is configured to write a data session and will write a data session in Joliet format. In one embodiment, a user can manually change or modify default settings, but all that is required to achieve the default settings such as the configuration for Joliet format is the selection of an MP3 project as shown in operation 112.

The method continues with operation 114 in which a user then browses and selects desired MP3 files. In selecting an MP3 project in operation 112, a user need not know that MP3 files are data files, and further, a user need not browse through all types of data files in a source location. In one embodiment, the selection of an MP3 project in operation 112 activates a filter so that in operation 114, a user need only browse MP3 files in a source location. The filter would parse the files at a source to display only a target format, in this example MP3 files, for a user to browse and from which to select files to be burned to a destination optical media. In one embodiment, a user could modify the filter to allow browsing of wav, .cda, la1, .lqt, mid, .wma, and any other desired audio or data file. While a more experienced and knowledgeable user might recognize that different file types may require conversion in order to play on an optical media of MP3 files, the method filters out everything but MP3 files, in one embodiment, so that a user need only select the desired files from a source of files that are filtered to display only those files, MP3, that are in the desired destination media format.

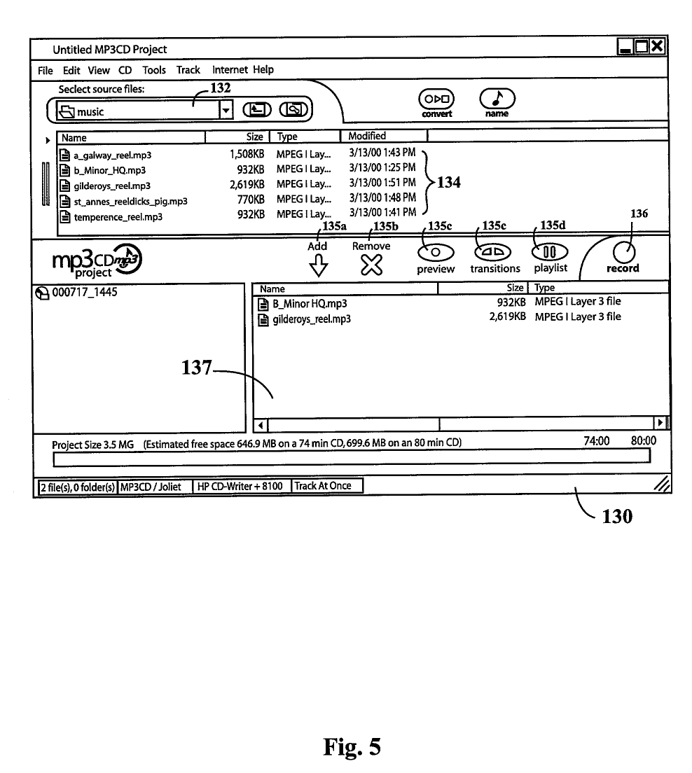

FIG. 5 shows an exemplary MP3 CD project screen 130 for recording MP3 files in accordance with one embodiment of the invention. A source location is identified at .132, and only those source files of the desired format, MP3 in this example, are presented for browsing at 134. In one embodiment, file manipulation buttons such as 135a-135d provide a plurality of options to manipulate files in the project. By way of example, a file selected from the files presented for browsing in 134 can be added to the MP3 project using add button 134a. As files are added to the project, they are presented in the order they were added in 137. In one embodiment, a file can be removed from the project by selecting the file in 137, and then selecting the remove button 135b. A plurality of file manipulation options are available to a user through file manipulation buttons 135a-135d, shown as exemplary functions only, and other available menus and data manipulation techniques such as pull-down menus, mouse right-click menus, and the like.

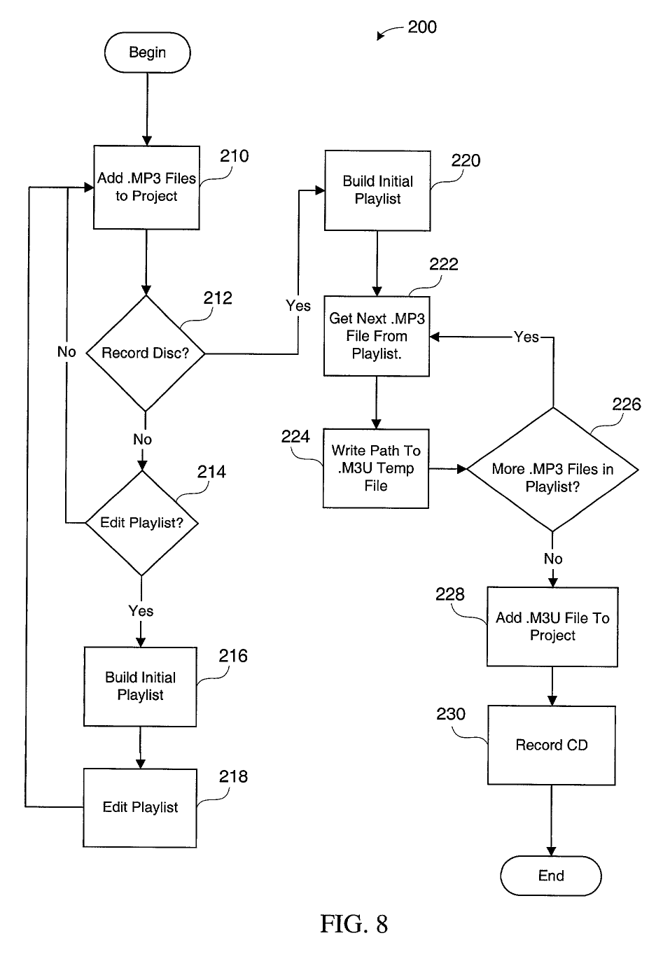

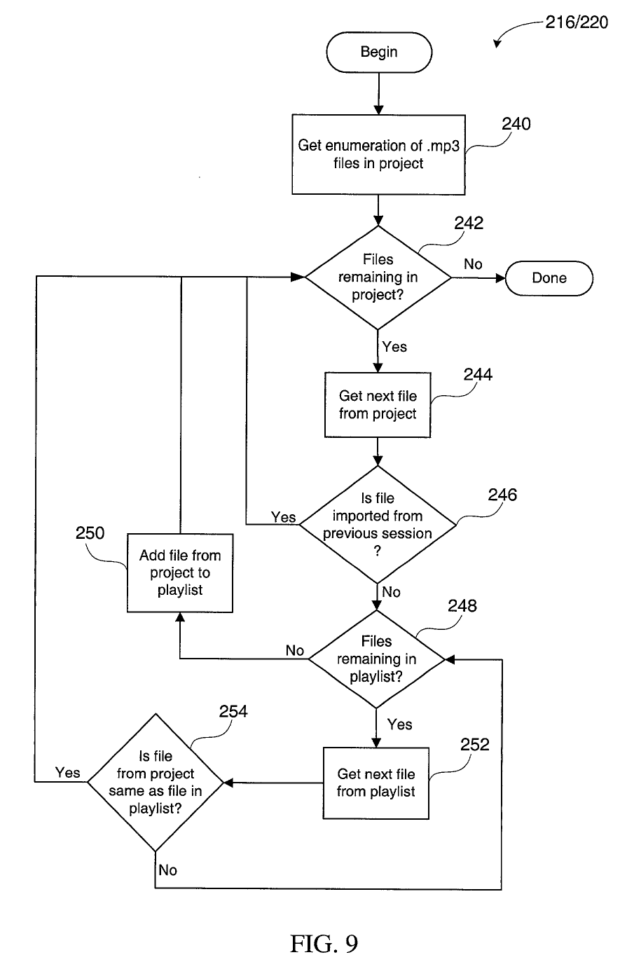

Returning once again to FIG. 3, the method then proceeds to operation 116 in which the selected files are ordered as desired. In operation 116, a user can order or sequence the selected files to create a playlist, during file selection or project creation, that will play the files in the desired sequence once the files have been written to the destination optical media. In one embodiment of the invention, the user can create a playlist of the selected files at the time of selection of the files and prior to the files being written to the destination optical media providing a more convenient time for a user to create a playlist. As will be described in detail in reference to FIGS. 8-9, although a playlist can be created at the time of selection of files and while the selected files are in a source location or locations, the playlist is created to identify and play the MP3 files from the destination optical media. The user is therefore able to create or edit a playlist at the most convenient and efficient time, when the files are selected to be written to optical media, and the playlist will identify and play the selected files from the destination location.

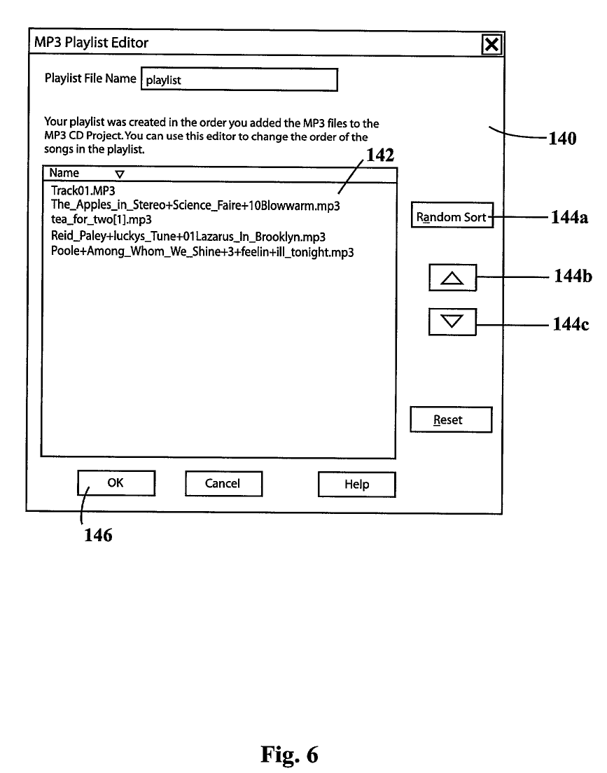

FIG. 6 shows an exemplary MP3 playlist editor screen 140 for editing the MP3 project playlist in accordance with one embodiment of the invention. In one embodiment, the MP3 playlist editor screen 140 of an optical media recording application is presented in response to a file manipulation function to edit the playlist. By way of example, selecting the playlist button 135d shown in FIG. 5 presents a user with an MP3 playlist editor screen 140 such as illustrated in FIG. 6. The MP3 files that have been added to the project are shown in a current order in 142, and sequencing buttons such as 144a-144c provide a user with a plurality of options for sequencing the MP3 project files. Once the desired order for the playlist is achieved, the sequence is saved by closing the MP3 playlist editor screen 140 with close button 146.

Once again in FIG. 3, the method proceeds to operation 118 and the selected files are written to the destination media. In one embodiment of the invention, the playlist is written to the destination optical media in addition to the selected MP3 files. The playlist file is configured, in one embodiment, to be associated with a media player so that if the playlist is executed, a media player is launched and plays the identified files in the playlist. In one embodiment, a media player is written to the destination media in order to play MP3 files whether or not a media player is resident on a host system that may receive the optical media. In another embodiment, an auto-run file is written to the destination optical media with the selected files in operation 118 with an executable file that checks to see if the playlist file (M3U) is a registered file type. If the M3U file is a registered file type and associated with the system media player, then the host system media player is launched when the optical media is inserted into an optical media playback device on a host system, and begins playing the songs on the playlist. A typical user, however, need only select a record function such as the record button 136 shown in the exemplary MP3 project screen 130 of FIG. 5, and in operation 118, the selected files are written to the optical media. If additional features such as media players and executables to launch media players are to be included on the destination optical media, they are written during the record operation 118, and the method is done.

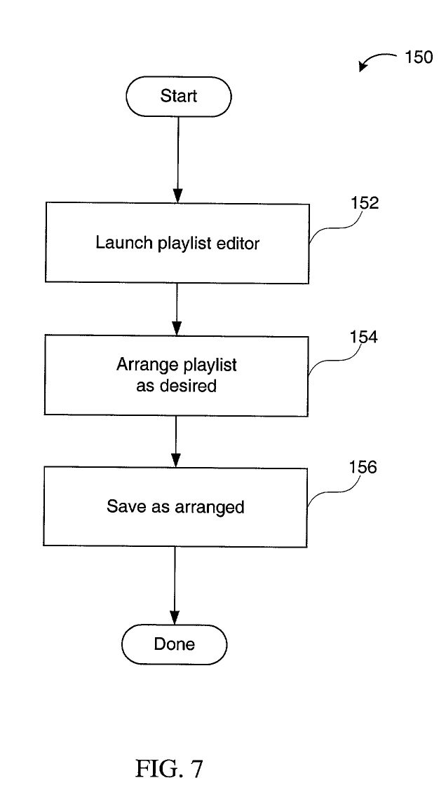

FIG. 7 is a flowchart diagram 150 illustrating the method operations of creating a playlist in accordance with one embodiment of the present invention. One embodiment of the present invention provides for the creation of a playlist at the time of the selection of the files that are to be recorded to optical media. The method begins with operation 152 and launching the playlist editor. In one embodiment, a user is selecting files to record as MP3 files to optical media. During the selection of files, the user may desire to create a playlist of the selected files, and in operation 152, the user opens a playlist editor interface. In one embodiment, a user is presented with an MP3 playlist editor screen 140 of the optical media recording application such as the one described above in reference to FIG. 6.

The method proceeds with operation 154 in which the user arranges the selected files in a playlist as desired. In operation 154, a user can determine and set the sequence in which the MP3 files in the project are played from the destination optical media. In one embodiment, the user can alternate between an interface to select files to add to the optical media, and the interface to arrange the playlist. In another embodiment, the user need only arrange the selected files for burning to the destination optical media as they are selected, and then save the arrangement at the completion of file selection as the desired playlist. The concluding operation 156 is the saving of the playlist as arranged, and the method is done.

FIG. 8 is a flowchart diagram 200 illustrating in greater detail the method operations performed to create and record optical media containing MP3 files in accordance with one embodiment of the present invention. The method begins with operation 210 in which MP3 files are added to a project. As used herein, “project” refers to the collection of files that have been or are being selected, arranged, formatted, and recorded to optical media to create an MP3 compact disc. Operation 210 represents the on-going selection of files to record to optical media.

In decision block 212, the method determines whether the compact disc is ready to be recorded with the selected files. If the compact disc is to be recorded at this point, a “yes” to decision block 212, then the method advances to operation 220 which is described below. If the compact disc is not to be recorded at this point, a “no” to decision block 212, the method advances to decision block 214 where it is determined whether or not the playlist is to be edited. As described above in reference to FIG. 7, one embodiment of the present invention provides for playlist editing coincident with file selection. By way of example, if a file is added in operation 210 to a collection of files, a user may desire the just added file to be the first file played in the collection of MP3 files. In this example, the answer to decision block 214 would be “yes” and the method would advance to operation 216. If, however, the user has added a file in operation 210 at precisely the desired point in the collection of MP3 files, then the response to decision block 214 would be “no” and the method would loop back to operation 210 to add more files to the project. In the embodiment illustrated, a user can add files to the project, and edit the playlist at any time during the process of file selection.

If the playlist is to be edited, a “yes” to decision block 214, the method advances to operation 216 to build an initial playlist. As described in greater detail in reference to FIG. 9, the initial playlist is created from which a temporary file is written that establishes a projected map to each of the selected files on the destination optical media. Since the files have not actually been written to the destination optical media at this point in the method, the initial playlist created in 216 is a virtual playlist that may become the actual playlist in a final version when the files are finally recorded to the destination optical drive.

In one embodiment of the invention, an initial playlist is created in operation 216 in order to edit the sequence or iterations of the files selected in operation 210. If, by way of example, selected files were added in exactly the desired sequence in operation 210, then when all the desired files have been added and the disc is ready to be recorded, the initial playlist is created in operation 220, which is discussed in greater detail below. If, however, editing is desired that would alter the sequence or iterations from the initial selections made in operation 210, then an initial playlist is created in operation 216 that mirrors the selections made in operation 210. The initial playlist created in operation 216 is then edited as desired in operation 218. Following the editing of the playlist in operation 218, the method loops back to operation 210 to add additional files to the project until the project is ready to be recorded.

When a user has selected all the desired files for a project and is ready to record a compact disc of MP3 files (a “yes” to decision block 212), the method advances to operation 220 in which an initial playlist is built. In one embodiment, the building of an initial playlist in operation 220 is the same functional operation as the building of an initial playlist in operation 216. The initial playlist in operation 216 is built so that it may be edited. As described above, the initial playlist mirrors the files as selected in operation 210. By way of example, in one embodiment a selection interface is presented to a user that adds selected files to a region of the interface as the files are selected and added to the project. Such a region of the selection interface is shown as 137 in FIG. 5. When the initial playlist is built in either operation 216 or operation 220, the initial playlist is created as a list of the same files and in the same order as those files in the region of the selection interface. Once the initial playlist is built in operation 220 in preparation to record the compact disc, the method advances to operation 222.

Each file is examined, in sequence, in operation 222. The initial playlist built in operation 220 provides a sequential listing of the MP3 files to be recorded to the destination optical media. In operation 222, the files are examined, one at a time to create what will be the playlist for the files on the destination optical media. Upon obtaining a next file from the initial playlist in operation 222, the method advances to operation 224 where a path to the file obtained in operation 222 is written to a .m3u (M3U) temporary file. As is known, an M3U file is a playlist file. An M3U file is simply a text file that is line delimited containing the file paths to the MP3 files in the order to be played. In operation 224, the M3U file is created as a temporary file that will be added in its final form to the MP3 project and written to the destination optical media. As a temporary file, the M3U is a virtual playlist that maps each of the files or songs to the destination media prior to the actual record operation.

The M3U temporary file is the projection of the destination file path for each of the MP3 files. When the M3U playlist is executed from the destination optical media, the playlist serves as a list of pointers to direct a media player to each of the files, in order, on the playlist to be played. The file path, therefore, necessarily is to the optical media on which the files will be recorded. It should be noted that the media recording application will record the selected files to the destination optical media, and therefore must identify a file path to the selected file at the source location for the process of recording, but this is not the information contained in the M3U playlist file.

The method then advances to decision block 226 in which it is determined whether there are more MP3 files in the initial playlist created in operation 220. If there are more files, a “yes” to decision block 226, the method loops back to operation 222 and obtains the next file from the initial playlist. This loop is maintained or repeated until all of the files from the initial playlist are examined and the paths written to the temporary M3U file. When no more MP3 files remain in the initial playlist, a “no” to decision block 226, the method advances to operation 228.

In operation 228, the temporary M3U file is added as an M3U file in its final form to the project. The M3U file is a data structure just as the MP3 files are data structures. The method then advances to operation 230 and the project which, as illustrated in the embodiment of flowchart 200 contains MP3 files and an M3U playlist file, is recorded to the destination optical media. Once the recording operation is completed, the method is done.

FIG. 9 is a flowchart diagram illustrating in greater detail the method operations of building an initial playlist of operations 216 and 220 from FIG. 8. As described above in reference to FIG. 8, the initial playlist is created, and from the initial playlist a temporary file is written that establishes a projected map to each of the selected files for the MP3 project on the destination optical media. The initial playlist, therefore, tracks the MP3 files as they are added to the project, and can be edited in accordance with a user's desire to modify the sequence of selected files.

The method begins with operation 240 and the obtaining of an enumeration of the MP3 files in the project. In one embodiment, a selection interface is presented to a user during the selection of files to add to the MP3 project. As files are selected and added, the song name, which in one embodiment can be edited as desired, appears in a selection box of the selection interface. As illustrated in FIG. 5, the files selected from 134 and added to the MP3 project are listed in 137 in the order they are added to the MP3 project. As described above in reference to FIG. 8, so long as songs are added to the project in the desired order of playback, the user has no need to edit the playlist, and continues to select songs until ready to record to the destination optical media The song names listed in the selection box, in the exemplary application, are a graphical representation of the enumeration of the MP3 files in the project that are obtained in operation 240.

In decision block 242, an initial examination loop is established to enable examination of each of the MP3 files in the project to create the initial playlist. The MP3 files in the project are examined one by one as illustrated. If an MP3 file exists in the project, a “yes” to decision block 242, the method advances to operation 244 where the next file is obtained for examination. In decision block 246, it is determined if the selected MP3 file has been recorded to the destination optical media in a previous session. If the selected file has been recorded in a previous session to the same destination optical media, a “yes” to decision block 246, the method loops back to decision block 242 to determine if there is another MP3 file to examine. In one embodiment, decision block 246 is implemented because the previous recording session will be combined with the current project, and therefore the selected file as well as a previous corresponding playlist entry already exist on the destination optical media and will not be re-recorded. If the selected MP3 file has not been previously recorded to the destination optical media, the method advances to decision block 248.

Decision block 248 establishes an examination loop to ensure the same MP3 file is not inadvertently duplicated in the playlist. The method examines the playlist it is creating, and if there are files in that playlist, a “yes” to decision block 248, the method looks at each file in the playlist one at a time. In operation 252, the method gets a next file in the playlist, and then determines in decision block 254 if the file from the project (obtained in operation 244) is the same as the file in the playlist (from operation 252). If the file is a duplicate, the response to decision block 254 is yes. The method then loops back to decision block 242 without adding the duplicate entry to the playlist.

If the project file is not the same as the playlist file, a “no” to decision block 254, the method loops back to decision block 248 to check the next file in the playlist, if there are more files in the playlist to examine. In this manner, as each MP3 file is added to the project, the file is compared to every other file already added to the project and entered in the playlist to ensure the selected file is not a duplicate file entry. If the project file is not on the playlist after each playlist entry has been examined, a “no” to decision block 248, the method proceeds through operation 250 where the project file is added to the playlist, and then advances to the next project file through decision block 242. If the project file is the same as a playlist file, a “yes” to decision block 254, the method loops back to the next project file through decision block 242 without adding a duplicate of the file to the playlist.

In one embodiment, the only circumstance that would result in a “no” to decision block 248 is the very first MP3 file that is examined. After the first file is examined and added to the play list, there will always be at least one file on the playlist to which subsequent files are compared. Additionally, one embodiment of the invention might not result in a “no” to the first project file examined. In one embodiment, if there is a prior session on the destination optical media, the prior session playlist is imported into the current project as the starting point for the playlist. In this manner, the first project file, if not imported from a previous session, would be compared to each file in the prior session playlist.

The illustrated embodiment assumes that duplication of songs is not desired, and the method operations, as shown, include comparisons to ensure no song is duplicated on the playlist. Duplication, however, may be desired and, in an embodiment of the invention, a user can configure the invention to allow duplication, or to provide a user alert when a duplicate MP3 file is selected to be added to the project, and a selectable option of duplication.

The invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form part of the invention are useful machine operations. The invention also relates to a device or an apparatus for performing these operations. The apparatus may be specially constructed for the required purposes, or it may be a general purpose computer selectively activated or configured by a computer program stored in the computer. In particular, various general purpose machines may be used with computer programs written in accordance with the teachings herein, or it may be more convenient to construct a more specialized apparatus to perform the required operations.

The invention can also be embodied as computer readable code on a computer readable medium. The computer readable medium is any data storage device that can store data, which can thereafter be read by a computer system. Examples of the computer readable medium include read-only memory, random-access memory, CD-ROMs, CD-Rs CD-RWs, magnetic tapes, and other optical data storage devices. The computer readable medium can also be distributed over network coupled computer systems so that the computer readable code is stored and executed in a distributed fashion.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method for recording MP3 files to optical media, comprising:
browsing MP3 files at a source location;
selecting MP3 files to record to a destination optical media;
constructing a playlist of the selected MP3 files to be executed from the destination optical media; and
recording the selected MP3 files and the playlist to the destination optical media.

2. A method for recording MP3 files to optical media as recited in claim 1, further comprising:
running a media recording application; and
selecting an MP3 project of the media recording application.

3. A method for recording MP3 files to optical media as recited in claim 2, wherein the selecting of an MP3 project configures the media recording application for a data recording session.

4. A method for recording MP3 files to optical media as recited in claim 3, wherein a format for the data recording session is Joliet.

5. A method for recording MP3 files to optical media as recited in claim 2, wherein the selecting of an MP3 project generates a graphical user interface to display the MP3 files for browsing and selecting.

6. A method for recording MP3 files to optical media as recited in claim 5, wherein the selecting of an MP3 project activates a filter to display only MP3 files located in a source location.

7. A method for recording MP3 files to optical media as recited in claim 1, further comprising:
editing the playlist prior to recording the selected MP3 files and the playlist to the destination optical media.

8. A method for recording MP3 files to optical media as recited in claim 7, wherein the editing the playlist generates a graphical user interface enabling the setting of a sequence for playback of the selected MP3 files after the recording of the selected MP3 files to the destination optical media.

9. A method for recording MP3 files to optical media as recited in claim 7, wherein the playlist maps a file path for each of the selected MP3 files to the destination optical media.

10. Computer readable media having program instructions for recording data to optical media, the computer readable media comprising:
program instructions for receiving a project selection;
program instructions for configuring and formatting a recording session in accordance with the received project selection;
program instructions for parsing source files and filtering out those files not in a target format of the received project selection;
program instructions for receiving a selection of source files to be recorded to the optical media;
program instructions for constructing a playlist of the source files to be executed from the destination optical media; and
program instructions for recording the selection of source files and the playlist to the optical media.

11. Computer readable media having program instructions for recording data to optical media as recited in claim 10, wherein the project selection is MP3.

12. Computer readable media having program instructions for recording data to optical media as recited in claim 10, wherein the configuring and formatting the recording session includes configuring and formatting the optical media for a data session.

13. Computer readable media having program instructions for recording data to optical media as recited in claim 12, wherein a format for the data session is Joliet.

14. Computer readable media having program instructions for recording data to optical media as recited in claim 10, wherein the playlist maps a file path for each one of the selection of source files to the optical media.

15. An optical media recording program configured to record data to optical media, comprising instructions for:
searching for music data files from at least one source, the searching being configured to only display the music data files at the exclusion of non-music data files;
enabling the selection of particular ones of the music data files;
building a data structure including the selected music data files, the data structure further including a playlist data structure defining an order for playing the selected music files; and
recording the selected music data files including the playlist data structure to an optical disc from the at least one source;
whereby the selected music data files are configured to be accessed for playing from the optical disc in the order defined by the playlist data structure.

16. An optical media recording program configured to record data to optical media as recited in claim 15, wherein a format of the music data files is MP3.

17. An optical media recording program configured to record data to optical media as recited in claim 15, wherein the playlist data structure maps a file path for each of the selected music data files to the optical disc.

18. An optical media recording program configured to record data to optical media as recited in claim 16, wherein the searching for music data files includes scanning music data files in the at least one source location which are in the MP3 format and displayed in a graphical user interface that identifies the at least one source and the music data files.

19. An optical media recording program configured to record data to optical media as recited in claim 16, wherein the selection of particular ones of the music data files is enabled by generating a graphical user interface that displays the music data files in the at least one source location and provides for selection of particular ones of the music data files and a separate display of the selected particular ones of the music data files.

20. An optical media recording program configured to record data to optical media as recited in claim 15, wherein the building a data structure includes keeping a list in memory of the selected particular ones of the music data files in an order in which the selected particular ones of the music data files were selected.

21. In a computer system including an attached peripheral storage device and an attached optical disc recording device, the computer system having a processor and memory for executing program instructions stored at least in part in the attached storage device, program instructions including:
instructions for receiving a project selection;
instructions for configuring a recording session in accordance with the received project selection;
instructions for parsing source files and filtering out those files not in a format of the received project selection;
instructions for receiving a selection of source files to be recorded to a destination optical media;
instructions for constructing a playlist of the source files to be executed from the destination optical media; and
instructions for recording the selection of source files and the playlist in a format of the received project selection.

22. In a computer system including an attached peripheral storage device and an attached optical disc recording device, the computer system having a processor and memory for executing program instructions stored at least in part in the attached storage device, program instructions as recited in claim 21, wherein the project selection is MP3.

23. In a computer system including an attached peripheral storage device and an attached optical disc recording device, the computer system having a processor and memory for executing program instructions stored at least in part in the attached storage device, program instructions as recited in claim 21, wherein the receiving the selection of source files to be recorded to the destination optical media is through a graphical user interface that displays source files in the format of the received project selection.

24. In a computer system including an attached peripheral storage device and an attached optical disc recording device, the computer system having a processor and memory for executing program instructions stored at least in part in the attached storage device, program instructions as recited in claim 21, wherein the playlist maps a file path for each of the selection of source files to the destination media.

25. In a computer system including an attached peripheral storage device and an attached optical disc recording device, the computer system having a processor and memory for executing program instructions stored at least in part in the attached storage device, program instructions as recited in claim 24, wherein the playlist can be edited after receiving a selection of source files to be recorded to the destination optical media.

26. In a computer system including an attached peripheral storage device and an attached optical disc recording device, the computer system having a processor and memory for executing program instructions stored at least in part in the attached storage device, program instructions as recited in claim 25, wherein the playlist can be combined with an imported playlist, the imported playlist being from a previous session recorded to the destination optical media.
